(19) United States
(12) Patent Application Publication
(10) Pub. No.: US 2012/0228666 A1
(43) Pub. Date: Sep. 13, 2012

(54) Optoelectronic Module

(75) Inventors: Karl Weidner, Muenchen (DE); Matthias Rebhan, Riemerling (DE); Axel Kaltenbacher, Mintraching (DE); Walter Wegleiter, Nittendorf (DE); Bernd Barchmann, Regensburg (DE)

(73) Assignee: OSRAM OPTO SEMICONDUCTORS GMBH, Regensburg (DE)

(21) Appl. No.: 13/496,805

(22) PCT Filed: Sep. 6, 2010
(86) PCT No.: PCT/EP2010/063035

§ 371 Date: May 29, 2012

(30) Foreign Application Priority Data
Sep. 18, 2009 (DE) 10 2009 042 205.6

(51) Int. Cl. H01L 33/36

(52) U.S. Cl. 257/99; 257/E33.062

(57) ABSTRACT

An optoelectronic module has at least one carrier with at least one contact location. A semiconductor chip emitting radiation includes a first contact surface and a second contact surface. An electrically insulating layer has a first and a second recess. The first contact surface is disposed on the side of the semiconductor chip emitting radiation facing away from the carrier. The electrically insulating layer is applied at least in places to the carrier. The semiconductor chip includes the first recess in the area of the first contact surface and the second recess in the area of the contact location. A electrically conductive conductor structure is disposed on the electrically insulating layer. The first contact surface electrically contacts the contact location of the carrier. The electrically insulating layer is formed predominately from a ceramic material.

This patent application is a national phase filing under section 371 of PCT/EP2010/063035, filed Sep. 6, 2010, which claims the priority of German patent application 10 2009 042 205.6, filed Sep. 18, 2009, each of which is incorporated herein by reference in its entirety.

### SUMMARY OF THE INVENTION

An optoelectronic module is specified.

One aspect of the invention provides an optoelectronic module that is particularly stable with respect to aging and has a high lifetime.

In accordance with at least one embodiment of the optoelectronic module, the module comprises a carrier having at least one contact location. The carrier can be a printed circuit board or a leadframe. It is likewise conceivable for the carrier to be embodied in flexible fashion and, for example, as a film. The carrier can be formed with an electrically conducting material, for example, a metal, or an electrically insulating material, for example, a thermosetting plastic material or a thermoplastic material or else a ceramic material. If the carrier is formed with an electrically insulating material, it is conceivable for the carrier to have connection locations and conductor tracks at a mounting area and/or a base area lying opposite the mounting area. The at least one contact location is formed with an electrically conductive material, for example, a metal.

In accordance with at least one embodiment, the optoelectronic module comprises a radiation-emitting semiconductor chip, wherein the radiation-emitting semiconductor chip has a first contact area and a second contact area. The two contact areas serve for making contact with the radiation-emitting semiconductor chip. By way of example, the radiation-emitting semiconductor chip is fixed and electrically contact-connected by the second contact area on a connection location of the carrier. The radiation-emitting semiconductor chip can be a luminescence diode chip, for example. The luminescence diode chip can be a light-emitting or laser diode chip. The radiation-generating active zone emits radiation in the range of ultraviolet to infrared light. The first and second contact areas of the radiation-emitting semiconductor chip are preferably formed with an electrically conductive material, for example, a metal.

In accordance with at least one embodiment, the optoelectronic module comprises an electrically insulating layer having a first and a second cutout. By way of example, the cutouts are produced by means of material removal. The two cutouts are then delimited, for example, laterally by the electrically insulating layer and each have two openings lying opposite one another. Preferably, the two cutouts are then freely accessible from outside.

In accordance with at least one embodiment of the optoelectronic module, the first contact area is arranged on that side of the radiation-emitting semiconductor chip which faces away from the carrier. By way of example, the first contact area is applied at the surface on that side of the radiation-emitting semiconductor chip which faces away from the carrier.

In accordance with at least one embodiment, the optoelectronic module comprises at least one electrically conductive conducting structure. The electrically conductive conducting structure can be, for example, electrical conductor tracks which are preferably formed with a metal or a metal alloy. It is likewise conceivable for the electrically conductive conducting structure to be formed with an electrically conductive adhesive or a metal paste.

In accordance with at least one embodiment of the optoelectronic module, the electrically insulating layer is applied to the carrier and the semiconductor chip at least in places. Preferably, the electrically insulating layer is formed in a positively locking manner at these locations, such that neither a gap nor an interruption is formed between the electrically insulating layer and the locations covered by the electrically insulating layer.

Furthermore, the electrically insulating layer has the first cutout in the region of the first contact area and the second cutout in the region of the contact location. Cutout and contact areas/contact locations are thus arranged congruently with respect to one another at least in places, such that the radiation-emitting semiconductor chip can be contact-connected externally through the cutouts introduced in the electrically insulating layer.

In accordance with at least one embodiment of the optoelectronic module, the electrically conductive conducting structure is arranged on the electrically insulating layer and electrically contact-connects the first contact area to the contact location of the carrier. Preferably, the electrically conductive conducting structure is formed in a positively locking manner onto the electrically insulating layer. In other words, preferably neither a gap nor an interruption is formed between the electrically insulating layer and the electrically conductive conducting structure. For this purpose, the electrically conductive conducting structure is applied to the electrically insulating layer, for example, by means of screen printing, a jet or dispensing method or a spraying method. By way of example, the cutouts are filled with the conducting structure at least in places. Preferably, the electrically conductive conducting structure penetrates through the cutouts, such that the electrically conductive conducting structure is completely contact-connected to the semiconductor chip. The cutout is filled, for example, with the material of the electrically conductive conducting structure.

In accordance with at least one embodiment of the optoelectronic module, the electrically insulating layer is predominantly formed with a ceramic material. “Predominantly” means that the electrically insulating layer contains at least 50% by weight, preferably at least 75% by weight, of ceramic material. In this context, it is also conceivable for the electrically insulating layer to completely consist of a ceramic material. Furthermore, it is possible for the electrically insulating layer to consist of a glass ceramic produced from a glass melted by controlled crystallization.

In accordance with at least one embodiment, the optoelectronic module comprises a carrier having at least one contact location and a radiation-emitting semiconductor chip, wherein the radiation-emitting semiconductor chip has a first contact area and a second contact area. Furthermore, the optoelectronic module comprises an electrically insulating layer having a first and a second cutout, and also at least one electrically conductive conducting structure. The first contact area is arranged on that side of the radiation-emitting semiconductor chip which faces away from the carrier. Furthermore, the electrically insulating layer is applied to the carrier and the semiconductor chip at least in places and has the first cutout in the region of the first contact area and the second cutout in the region of the second contact location. The electrically conductive conducting structure is arranged on the electrically insulating layer and electrically contact-connects the first contact area to the contact location of the carrier. Furthermore, the electrically insulating layer is predominantly formed with a ceramic material.

In this case, the optoelectronic module described here is based on the insight, inter alia, that an electrically insulating layer which is formed with organic materials and which is used, for example, in optoelectronic modules with planar contact-connection is not very stable with respect to aging. That is to say that external influences such as, for example, irradiation, moisture or temperature fluctuations damage the material of the electrically insulating layer. This leads to a fragile electrically insulating layer, for example, even after a short operating duration of the optoelectronic module. That is to say that such an optoelectronic module can have damage caused by aging even after a short operating duration.

In order to provide an optoelectronic module which is particularly stable with respect to aging, the optoelectronic module described here makes use of the concept, inter alia, of forming the electrically insulating layer predominantly with a ceramic material. Ceramic materials are more stable with respect to aging particularly in the case of the external action of radiation and heat, as a result of which such an electrically insulating layer has hardly any material damage even under a high degree of external loading, even after a relatively long operating duration.

An optoelectronic module having a greatly increased lifetime is thus advantageously provided.

In accordance with at least one embodiment, the optoelectronic module comprises at least two radiation-emitting semiconductor chips, wherein the electrically insulating layer is arranged between the radiation-emitting semiconductor chips in places. By way of example, interspaces are formed between the semiconductor chips. In other words, the semiconductor chips are then arranged at a distance from one another. By way of example, the interspaces are filled with the material of the electrically insulating layer. Preferably, the electrically insulating layer then touches side areas of the semiconductor chips and covers the latter in a positively locking manner.

In accordance with at least one embodiment of the optoelectronic module, the electrically insulating layer, apart from the cutouts, is applied to the exposed outer areas of the optoelectronic module in a positively locking manner. That is to say that neither a gap nor an interruption is formed between the exposed outer areas of the optoelectronic module and the electrically insulating layer. In this case, the electrically insulating layer performs the function of an encapsulation layer, for example, of the radiation-emitting semiconductor chips. That can mean that the semiconductor chips are completely encapsulated by the electrically insulating layer apart from regions of electrical contact-connection. As a result, the radiation-emitting semiconductor chips are advantageously protected against mechanical influences, such as impacts, for example.

In accordance with at least one embodiment of the optoelectronic module, the electrically insulating layer is radiation-transmissive and covers a radiation exit area of the semiconductor chip in places. “Radiation-transmissive” means that the electrically insulating layer preferably only partly absorbs the radiation emitted by the active layer. The electromagnetic radiation emitted by the radiation-emitting semiconductor chips can thus be at least partly coupled out from the optoelectronic module through the electrically insulating layer.

In accordance with at least one embodiment of the optoelectronic module, the electrically insulating layer consists of a ceramic phosphor. If the electrically insulating layer is applied to the radiation exit area of the semiconductor chip in places, then the electrically insulating layer can partly absorb electromagnetic radiation primarily emitted by the semiconductor chip and at least partly convert the primarily emitted radiation into radiation having a different wavelength and re-emit it again. The electrically insulating layer therefore has the function of a light converter. By way of example, the electrically insulating layer then consists of YAG:Ce.

In accordance with at least one embodiment of the optoelectronic module, the first cutout in the electrically insulating layer runs continuously between the radiation exit area of the semiconductor chip and the carrier alongside areas of the semiconductor chip and is laterally delimited by the contact area and the carrier. That can mean that the radiation exit area and also one or more of the side areas of the semiconductor chip are “exposed” at least in places.

In accordance with at least one embodiment of the optoelectronic module, the first cutout in the electrically insulating layer runs continuously between adjacent semiconductor chips and is laterally delimited by the contact areas. In this context, “adjacent” means that the semiconductor chips are arranged in pairs, for example, and each pair forms the interspace between itself. The interspace is not covered by the electrically conducting layer and is therefore “exposed.” Furthermore, in this context it is conceivable that, alongside the exposed interspace, the radiation exit areas of the semiconductor chips are likewise free of the electrically insulating layer in places.

In accordance with at least one embodiment of the optoelectronic module, an insulation layer is arranged between the semiconductor chips. By way of example, the insulation layer fills the interspaces between the semiconductor chips in a positively locking manner at least in places. Furthermore, it is conceivable for the insulation layer and the electrically insulating layer to be formed with the same material.

In accordance with at least one embodiment of the optoelectronic module, the electrically insulating layer is a film. Preferably, the electrically insulating layer then has a layer thickness of 10 to 300 μm, preferably of 150 μm. It is likewise possible for the electrically insulating layer to consist of a multiplicity of individual films which can be arranged, for example, adhesively bonded, one above another and thus form a stacked film composite assembly. In this context, it is conceivable for the films to be hybrid films or else multilayer films. “Hybrid films” denotes, for example, a film formed with a ceramic material in a polymer matrix. “Multilayer films” are, for example, ceramic films with an adhesive coating.

In accordance with at least one embodiment of the optoelectronic module, the electrically insulating layer is applied by means of a laminating process. If the electrically insulating layer is a film, then it can be laminated by means of the laminating process onto exposed outer areas, for example, of the semiconductor chips and of the mounting area of the carrier.

In accordance with at least one embodiment of the optoelectronic module, the electrically insulating layer is applied by means of a sintering process. By way of example, for this purpose, the applied material of the electrically insulating layer is shaped by means of highly energetic laser light or by means of thermal sintering. For this purpose, the material of the electrically insulating layer is present, for example, in the form of a nanopowder or a composite.

In accordance with at least one embodiment, the electrically insulating layer is applied by means of a molding process. By way of example, for this purpose, before the material of the electrically insulating layer is applied, a die is applied to the contact locations/areas and covers the contact locations/areas. In a further step, the material of the electrically insulating layer can then be applied by injection molding. After curing, the dies can then be removed, thereby exposing the cutouts in the electrically insulating layer. Preferably, the material of the electrically insulating layer is then present in the form of a dispersion or an aerosol.

The features according to which the electrically insulating layer is applied by means of a laminating process, a sintering process or a molding process are features characterizing the device in each case, since the application method can be demonstrated directly on the optoelectronic module.

It is likewise conceivable for the electrically insulating layer to be sprayed on. For this purpose, the material of the electrically insulating layer is present, for example, in a volatile solution or in a polymer matrix.

Furthermore, the material of the electrically insulating layer can be applied by means of selective deposition, for example, by means of a plasma process, a plasma spray process or by means of sputtering.

It is likewise conceivable for the electrically insulating layer to be applied by means of a stencil printing method. For this purpose, a prefabricated stencil is placed onto the carrier and the semiconductor chips, the stencil having covers, for example, in the region of the contact locations/areas. By means of such a stencil grid, after the material has been applied by printing, regions remain free of the material of the electrically insulating layer, which regions then form the cutouts of the electrically insulating layer.

### BRIEF DESCRIPTION OF THE DRAWINGS

The optoelectronic module described here is explained in greater detail below on the basis of exemplary embodiments and the associated figures.

FIGS. 1 and 2 show schematic views of exemplary embodiments of an optoelectronic module described here; and

FIGS. 3a to 3d show individual production steps for producing an exemplary embodiment of an optoelectronic module described here.

In the exemplary embodiments and the figures, identical or identically acting constituent parts are in each case provided with the same reference symbols. The elements illustrated should not be regarded as true to scale; rather, individual elements may be illustrated with an exaggerated size in order to afford a better understanding.

### DETAILED DESCRIPTION OF ILLUSTRATIVE EMBODIMENTS

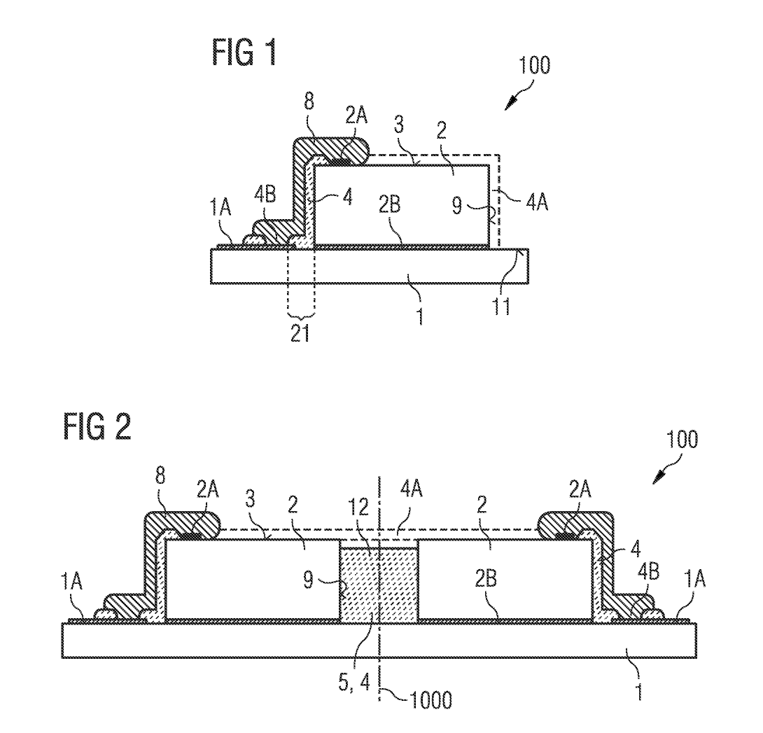

FIG. 1 shows, in a schematic side view, an exemplary embodiment of an optoelectronic module 100 described here. A carrier 1 has a contact location 1A. A radiation-emitting semiconductor chip 2 having an active zone for generating electromagnetic radiation is applied to a mounting area 11. Furthermore, the radiation-emitting semiconductor chip 2 has a first contact area 2A and a second contact area 2B. The radiation-emitting semiconductor chip 2 is applied by its second contact area 2B to the mounting area 11 of the carrier 1 and makes electrical contact there with the carrier 1. By way of example, the radiation-emitting semiconductor chip 2 is adhesively bonded or connected to the carrier 1 by means of a solder material. An electrically insulating layer 4 is applied in a positively locking manner to exposed side areas 9 of the semiconductor chip 2 and a radiation exit area 3 of the semiconductor chip 2 in places. Furthermore, the electrically insulating layer 4 covers the mounting area 11 of the carrier 1 in the region 21, such that the electrically insulating layer 4 runs without interruption between the contact location 1A and the first contact area 2A. The electrically insulating layer 4 has a first cutout 4A, which runs continuously between the radiation exit area 3 along the side area 9 as far as the carrier 1. The first cutout 4A is therefore laterally delimited by the carrier 1 and the first contact area 2A. The radiation exit area 3 of the radiation-emitting semiconductor chip 2 is then free of the electrically insulating layer 4 in places. An electrically conductive conducting structure 8 electrically contact-connects the first contact area 2A to the contact location 1A of the carrier 1. In the present case, the electrically conductive conducting structure 8 is printed on to the electrically insulating layer 4 and the two contact areas 1A and 2A. In the present case, the electrically insulating layer 4 is a film applied by means of a laminating process. In the exemplary embodiment in accordance with FIG. 1, the electrically insulating layer 4 consists of a ceramic material. It is likewise conceivable for the electrically insulating layer 4 to consist of a ceramic phosphor and for the electrically insulating layer 4 to at least partly convert electromagnetic radiation primarily emitted by the radiation-emitting semiconductor chip 2 into radiation having a different wavelength, such that the optoelectronic module 100 emits mixed light.

FIG. 2 shows the optoelectronic module 100 comprising two radiation-emitting semiconductor chips 2 arranged alongside one another. The semiconductor chips 2 form an interspace 12 between them, which is laterally delimited in each case by the side areas 9 and also by the carrier 1. An insulation layer 5 is arranged in the interspace 12, which insulation layer fills the interspace 12 at least in places and is applied to the side areas 9 and the carrier 1 in a positively locking manner. It is likewise conceivable that, instead of or in addition to the insulation layer 5, the electrically insulating layer 4 is introduced into the interspace 12. The first cutout 4A runs without interruption between the two semiconductor chips 2 and is laterally limited by the contact areas 2A. This has the consequence that the radiation exit areas 3 of the semiconductor chips are exposed at least in places.

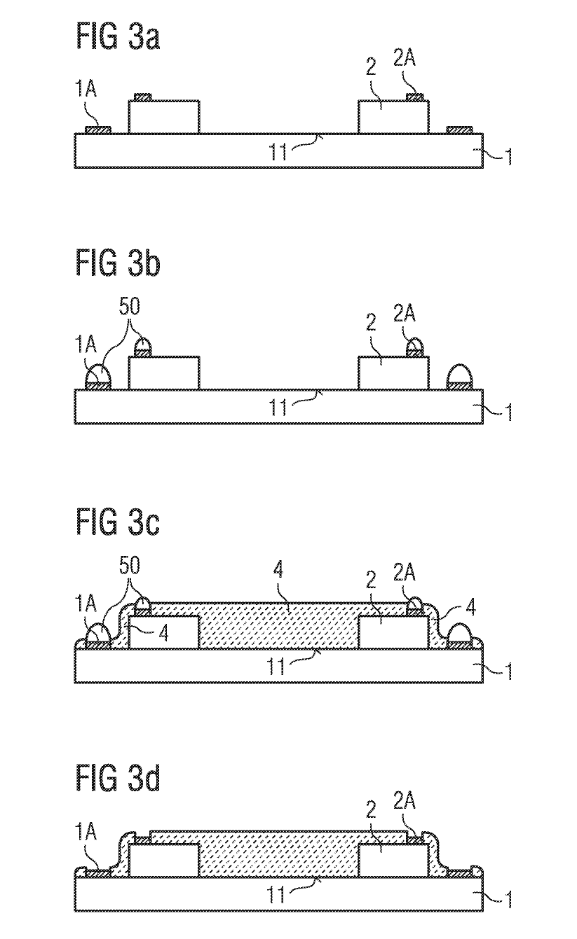

FIGS. 3a to 3d show individual production steps for producing an exemplary embodiment of an optoelectronic module 100 described here. For this purpose, firstly, as illustrated in FIG. 3a, the carrier 1 is provided, wherein the semiconductor chips 2 are applied to the mounting area 11 of the carrier 1.

In a further step, as shown in FIG. 3b, the contact areas 1A of the carrier 1 and the contact areas 2A of the semiconductor chips 2 are covered with a resist 50. Alternatively, the contact areas can be covered with films, a wax or other adhesion layers.

In accordance with FIG. 3c, in a further step, the material of the electrically insulating layer 4 is applied to exposed outer areas of the optoelectronic module 100, with the result that the side areas 9 and the radiation exit areas 3 are covered with the electrically insulating layer 4 at least in places. The application process can take place by means of a sintering or molding process, for example. It is likewise conceivable for the electrically insulating layer 4 to be applied by means of a laminating process or a spraying process.

Furthermore, the material of the electrically insulating layer 4 can be applied by means of selective deposition, for example, by means of a plasma process, a plasma spray process or by means of sputtering.

In a further step, in FIG. 3d, the resist 50 is removed by means of a physical and/or mechanical material removal, with the result that at least the contact areas 1A and 2A are exposed.

The radiation exit areas 3 are then completely covered with the material of the electrically insulating layer 4 apart from the locations at which the contact areas 2A run, wherein, in the present case, the electrically insulating layer 4 is formed with a radiation-transmissive ceramic or consists of a ceramic phosphor.

In a last step, the semiconductor chips 2 can be contact-connected via the electrically conductive conducting structures 8 at locations of the contact locations 1A and 2A.

Alternatively, the electrically insulating layer 4 can be applied by means of the use of a prepatterned mask. By way of example, the electrically insulating layer 4 can then be applied by a spraying process, for example, by means of plasma deposition.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or the exemplary embodiments.

1. An optoelectronic module, comprising
a carrier having a contact location;
a radiation-emitting semiconductor chip having a first contact area and a second contact area;
an electrically insulating layer having a first cutout and a second cutout; and
at least one electrically conductive conducting structure;
wherein the first contact area is arranged on a side of the radiation-emitting semiconductor chip that faces away from the carrier,
wherein the electrically insulating layer is applied to the carrier and the semiconductor chip at least in places and has the first cutout in a region of the first contact area and a second cutout in the region of the contact location,
wherein the electrically conductive conducting structure is arranged on the electrically insulating layer and electrically contact-connects the first contact area to the contact location of the carrier, and
wherein the electrically insulating layer is predominantly formed with a ceramic material.

2. The optoelectronic module according to claim 1, further comprising a second radiation-emitting semiconductor chip, wherein the electrically insulating layer is arranged between the radiation-emitting semiconductor chip and the second radiation-emitting semiconductor chip in places.

3. The optoelectronic module according to claim 1, wherein the electrically insulating layer, apart from the cutouts, is applied to the exposed outer areas of the optoelectronic module in a positively locking manner.

4. The optoelectronic module according to claim 1, wherein the electrically insulating layer is radiation-transmissive and covers a radiation exit area of the semiconductor chip at least in places.

5. The optoelectronic module according to claim 1, wherein the electrically insulating layer consists of a ceramic phosphor.

6. The optoelectronic module according to claim 1, wherein the first cutout in the electrically insulating layer runs continuously between the radiation exit area of the semiconductor chip and the carrier along side areas of the semiconductor chip and is laterally delimited by the first contact areas and the carrier.

7. The optoelectronic module according to claim 2, wherein the first cutout in the electrically insulating layer runs continuously between adjacent semiconductor chips and is laterally delimited by the contact areas.

8. The optoelectronic module according to claim 2, wherein an insulation layer is arranged between the semiconductor chips.

9. The optoelectronic module according to claim 1, wherein the electrically insulating layer comprises a film.

10. The optoelectronic module according to claim 9, wherein the electrically insulating layer comprises a laminated layer.

11. The optoelectronic module according to claim 1, wherein the electrically insulating layer is applied by a sintering process.

12. The optoelectronic module according to claim 1, wherein the electrically insulating layer is applied by a molding process.

13. An optoelectronic module, comprising:
a carrier having at least one contact location;
a radiation-emitting semiconductor chip, wherein the radiation-emitting semiconductor chip has a first contact area and a second contact area;
an electrically insulating layer having a first and a second cutout, wherein the electrically insulating layer is radiation-transmissive and covers a radiation exit area of the semiconductor chip at least in places and wherein the electrically insulating layer consists of a ceramic phosphor; and
at least one electrically conductive conducting structure,
wherein the first contact area is arranged on a side of the radiation-emitting semiconductor chip that faces away from the carrier,
wherein the electrically insulating layer is applied to the carrier and the semiconductor chip at least in places and has the first cutout in the region of the first contact area and the second cutout in the region of the contact location, and
wherein the electrically conductive conducting structure is arranged on the electrically insulating layer and electrically contact-connects the first contact area to the contact location of the carrier.

14. An optoelectronic module, comprising
a carrier having at least one contact location;
a plurality of radiation-emitting semiconductor chips, each radiation-emitting semiconductor chip having a first contact area and a second contact area;
an electrically insulating layer arranged between the radiation-emitting semiconductor chips, wherein the electrically insulating layer has a first and a second cutout; and
at least one electrically conductive conducting structure;
wherein the first contact area is arranged on a side of the radiation-emitting semiconductor chip that faces away from the carrier,
wherein the electrically insulating layer is applied to the carrier and at least one of the semiconductor chips at least in places and has the first cutout in the region of the first contact area and the second cutout in the region of the contact location,
wherein the electrically conductive conducting structure is arranged on the electrically insulating layer and electrically contact-connects the first contact area to the contact location of the carrier, and
wherein the electrically insulating layer is predominantly formed with a ceramic material.

15. The optoelectronic module according to claim 14, wherein an interspace is formed between the semiconductor chips, the interspace being laterally delimited by side areas of the semiconductor chip and the carrier.

16. The optoelectronic module according to claim 15, wherein the electrically insulating layer is arranged in the interspace and wherein the electrically insulating layer fills the interspace at least in places and is applied to the side areas and the carrier in a positively locking manner.

17. The optoelectronic module according to claim 15, wherein the first cutout runs without interruption between the semiconductor chips and is laterally limited by the contact areas, and wherein the radiation exit areas of the semiconductor chips are free of the electrically insulating layer at least in places.

18. The optoelectronic module according to claim 14, wherein the electrically insulating layer is radiation-transmissive and covers a radiation exit area and side areas of the semiconductor chip in a positively locking manner and wherein at least the contact areas and the contact locations are free of the electrically insulating layer.

19. The optoelectronic module according to claim 14, wherein the electrically insulating layer comprises a ceramic phosphor.

20. The optoelectronic module according to claim 14, wherein the electrically insulating layer is directly connected to the side areas of the semiconductor chip at least in places.
